(19) United States
(12) Patent Application Publication
(10) Pub. No.: US 2024/0422974 A1
(43) Pub. Date: Dec. 19, 2024

(54) MEMORY DEVICE AND METHOD OF MANUFACTURING THE SAME

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/490,976

(22) Filed: Oct. 20, 2023

(30) Foreign Application Priority Data
Jun. 13, 2023 (KR) 10-2023-0075462

(51) Int. Cl. H10B 43/27

(52) U.S. Cl. CPC H10B 43/27

(57) ABSTRACT

A memory device, and a method of manufacturing the same, includes cell plugs in addition to an insulating pattern provided on the cell plugs, the insulating pattern including openings corresponding to the cell plugs, respectively. The memory device also includes bit lines provided on the insulating pattern and bit line contacts provided in the openings to couple the cell plugs and the bit lines, respectively. The memory device further includes first air gaps provided between the bit lines. The memory device additionally includes second air gaps extending from the first air gaps and enclosed by the bit line contacts and the insulating pattern.

### CROSS-REFERENCE TO RELATED APPLICATION

The present application claims priority under 35 U.S.C. § 119 (a) to Korean patent application number 10-2023-0075462 filed on Jun. 13, 2023, in the Korean Intellectual Property Office, the entire disclosure of which is incorporated by reference herein.

### BACKGROUND

### 1. Technical Field

Various embodiments of the present disclosure generally relate to a memory device and a method of manufacturing the memory device, and more particularly, to a memory device including a bit line and a method of manufacturing the memory device.

### 2. Related Art

A memory device may be a nonvolatile memory device in which stored data is maintained even if supplied power is cut off. The nonvolatile memory device may be classified as a two-dimensional (2D) structure or a three-dimensional (3D) structure according to a structure in which memory cells are arranged. Memory cells of the nonvolatile memory device having the 2D structure may be arranged on a substrate in a single layer, while memory cells of the nonvolatile memory device having the 3D structure may be vertically stacked on the substrate. Because the integration degree of the nonvolatile memory device having the 3D structure is higher than that of the nonvolatile memory device having the 2D structure, electronic devices using the nonvolatile memory device having the 3D structure are increasingly being used.

### SUMMARY

An embodiment of the present disclosure is directed to a memory device. The memory device may include: cell plugs; an insulating pattern disposed on the cell plugs and including openings corresponding to the cell plugs, respectively; bit lines disposed on the insulating pattern; bit line contacts disposed in the openings to couple the cell plugs and the bit lines, respectively; first air gaps disposed between the bit lines; and second air gaps extending from the first air gaps and enclosed by the bit line contacts and the insulating pattern.

An embodiment of the present disclosure is directed to a method of manufacturing a memory device. The method may include: forming an insulating layer on cell plugs; etching a portion of the insulating layer to form openings that at least partially overlap the cell plugs; forming first material layers to fill respective lower portions of the openings; forming a lower sacrificial layer on an entire structure including the first material layers; forming a spacer pattern on the lower sacrificial layer to expose a portion of the lower sacrificial layer; etching the lower sacrificial layer exposed by the spacer pattern to form sacrificial openings that expose respective portions of the first material layers; filling the sacrificial openings with second material layers; removing the lower sacrificial layer; and forming a capping layer on the second material layers to form air gaps between the second material layers and between the second material layers and the openings.

### BRIEF DESCRIPTION OF THE DRAWINGS

FIG. 1 is a diagram illustrating a memory device according to an embodiment of the present disclosure.

FIG. 2 is a diagram illustrating the structure of a memory cell array according to an embodiment of the present disclosure.

FIG. 3 is a view illustrating the structure of a memory device according to an embodiment of the present disclosure.

FIGS. 4A to 4D are views illustrating the structure of a memory device according to an embodiment of the present disclosure.

FIGS. 5A to 5K are views illustrating a method of manufacturing a memory device according to an embodiment of the present disclosure.

FIG. 6 is a diagram illustrating a memory card system to which a memory device according to an embodiment of the present disclosure is applied.

FIG. 7 is a diagram illustrating a solid-state drive (SSD) system to which a memory device according to the present disclosure is applied.

### DETAILED DESCRIPTION

Specific structural or functional descriptions of embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application.

Various embodiments of the present disclosure will now be described in detail with reference to the accompanying drawings so that those skilled in the art can practice the technical spirit of the present disclosure.

Some embodiments of the present disclosure are directed to a technology for simplifying the manufacturing process of a memory device while improving the performance of the memory device including a bit line.

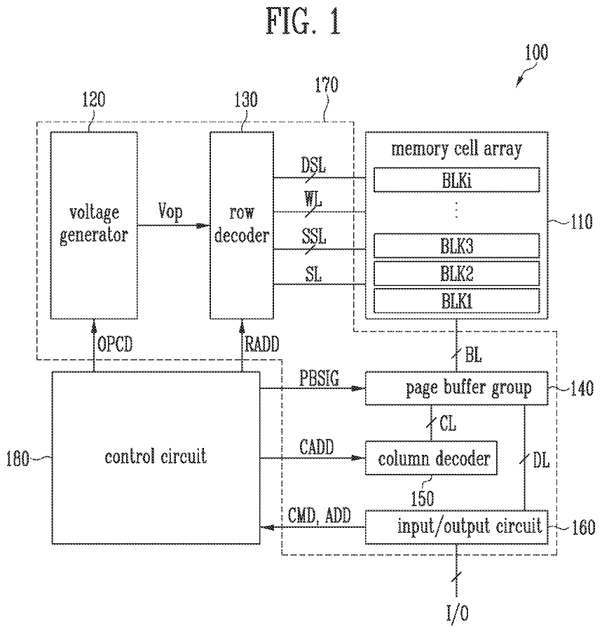

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include a plurality of memory cells in which data can be stored. Drain select lines DSL, word lines WL, source select lines SSL, and a source line SL may be coupled to each of the first to i-th memory blocks BLK1 to BLKi. Bit lines BL may be coupled in common to the first to i-th memory blocks BLK1 to BLKi.

Each of the first to i-th memory blocks BLK1 to BLKi may be implemented in a two-dimensional (2D) or three-dimensional (3D) structure. Each of the memory blocks having a 2D structure may include memory cells horizontally arranged on a substrate. Each of the memory blocks having a 3D structure may include memory cells stacked vertically on a substrate. Although the memory blocks formed in the 3D structure are described in the present embodiment for the convenience of description, the present embodiment may also be applied to the memory blocks each having the 2D structure.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop required for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be voltages that are applied to a selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off drain select transistors or source select transistors. For example, the turn-off voltage may be set to 0 V.

The precharge voltages are voltages higher than 0 V, and may be applied to the bit lines during a read operation. The verify voltages may be used for a verify operation of determining whether the threshold voltages of the selected memory cells have increased up to target levels. The verify voltages may be set to various levels depending on the target levels, and may be applied to the selected word line. The read voltages may be applied to the selected word line during a read operation on the selected memory cells. For example, the read voltages may be set to various levels according to the program scheme of the selected memory cells. The pass voltages may be voltages that are applied to unselected word lines, among the word lines WL, during a program or read operation, and may be used to turn on memory cells coupled to the unselected word lines. The erase voltages may be used for an erase operation of erasing the memory cells included in the selected memory block, and may be applied to the source line SL.

The row decoder 130 may transfer the operating voltages Vop to the drain select lines DSL, the word lines WL, the source select lines SSL, and the source line SL, which are coupled to a memory block selected in response to a row address RADD. For example, the row decoder 130 may be coupled to the voltage generator 120 through global lines, and may be coupled to the first to i-th memory blocks BLK1 to BLKi through the drain select lines DSL, the word lines WL, the source select lines SSL, and the source line SL.

The page buffer group 140 may include page buffers (not illustrated) coupled to the first to i-th memory blocks BLK1 to BLKi, respectively. For example, respective page buffers (not illustrated) may be coupled to the first to i-th memory blocks BLK1 to BLKi through bit lines BL. During a read operation, the page buffers (not illustrated) may sense currents or voltages of the bit lines that vary depending on the threshold voltages of selected memory cells in response to page buffer control signals PBSIG, and may temporarily store sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

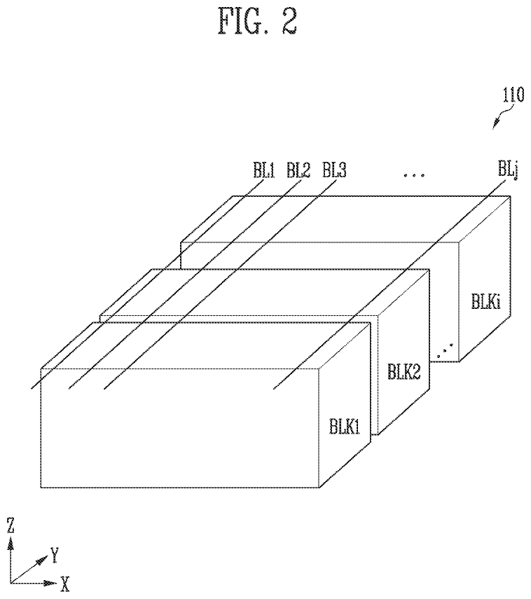

FIG. 2 is a diagram illustrating the structure of the memory cell array according to an embodiment of the present disclosure.

Referring to FIG. 2, the memory cell array 110 may include the first to i-th memory blocks BLK1 to BLKi. The first to i-th memory blocks BLK1 to BLKi may be arranged to be spaced apart from each other in a Y direction. The first to i-th memory blocks BLK1 to BLKi may extend in an X direction.

The first to i-th memory blocks BLK1 to BLKi may be coupled in common to first to j-th bit lines BL1 to BLj. For example, the first to j-th bit lines BL1 to BLj may extend in the Y direction, and may be arranged to be spaced apart from each other in the X direction. The first to j-th bit lines BL1 to BLj may be coupled, respectively, to the first to i-th memory blocks BLK1 to BLKi on the first to i-th memory blocks BLK1 to BLKi.

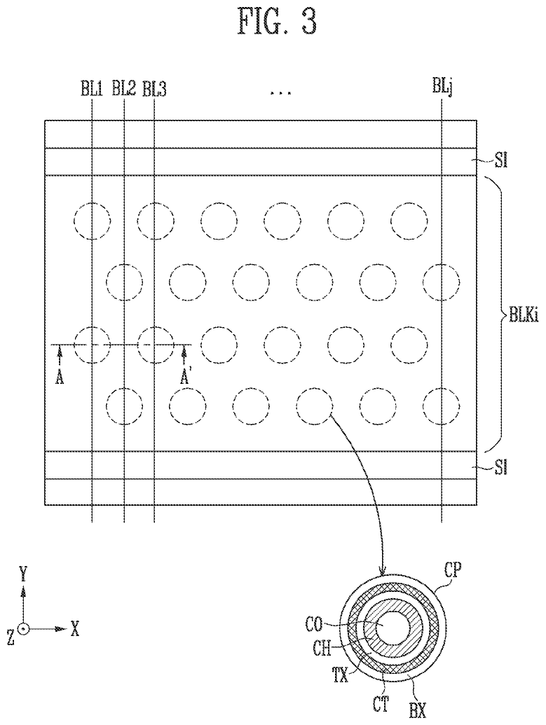

FIG. 3 is a view illustrating the structure of the memory device according to an embodiment of the present disclosure.

Referring to FIG. 3, the i-th memory block BLKi may be separated from neighboring memory blocks by a slit SI. For example, the slit SI may be positioned in the Y direction of the i-th memory block BLKi and may extend in the X direction. The i-th memory block BLKi may be adjacent to other memory blocks with the slit SI interposed therebetween.

The i-th memory block BLKi may include a plurality of cell plugs CP. The cell plugs CP may be formed in a vertical direction (e.g., Z direction) from the substrate (not shown). The cell plugs CP may be formed in a plurality of rows. Each row may include the cell plugs CP that are spaced apart from each other in the X direction. The plurality of rows may be spaced apart from each other in the Y direction. Centers of cell plugs CP included in odd-numbered rows and centers of cell plugs CP included in even-numbered rows may be offset from each other.

Each of the cell plugs CP may include a cylindrical blocking layer BX, a charge trap layer CT formed along an inner wall of the blocking layer BX, a tunnel isolation layer TX formed along an inner wall of the charge trap layer CT, a channel layer CH formed along an inner wall of the tunnel isolation layer TX, and a core pillar CO formed in a cylindrical shape in an area enclosed by the channel layer CH. Each of the blocking layer BX and the tunnel isolation layer TX may be formed of an oxide layer (e.g. silicon oxide layer). The charge trap layer CT may be formed of a nitride layer. The channel layer CH may be formed of a doped silicon layer. The core pillar CO may be formed of an insulating layer or a conductive layer. The blocking layer BX, the charge trap layer CT, the tunnel isolation layer TX, the channel layer CH, and the core pillar CO formed in the cell plug CP may extend in the vertical direction Z.

The first to j-th bit lines BL1 to BLj may be positioned on the i-th memory block BLKi. The first to j-th bit lines BL1 to BLj may be arranged to be spaced apart from each other in the X direction. Further, each of the first to j-th bit lines BL1 to BLj may extend in the Y direction.

Each of the first to j-th bit lines BL1 to BLj may be coupled to at least one cell plug CP. For example, the first bit line BL1 may be coupled to cell plugs CP included in the odd-numbered rows. Further, the second bit lines BL2 may be coupled to cell plugs CP included in the even-numbered rows.

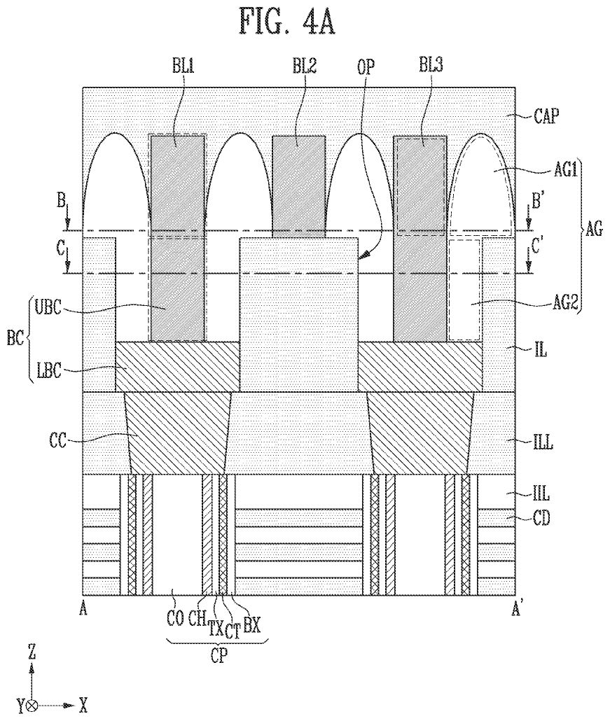

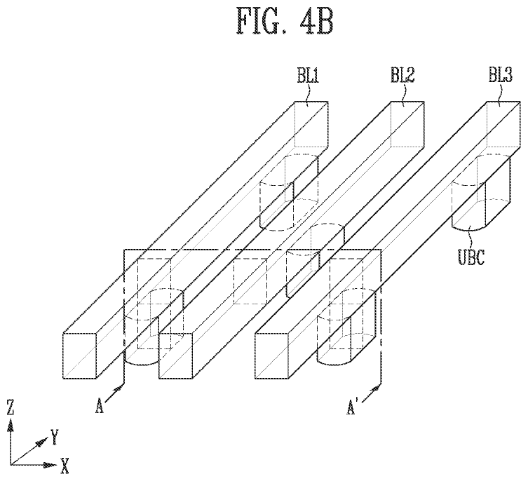

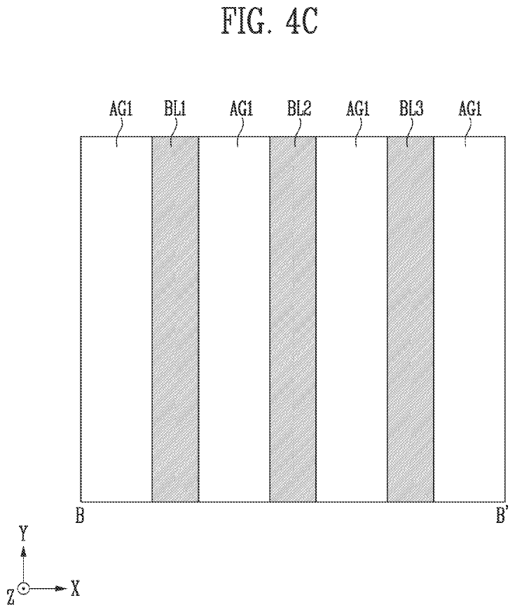

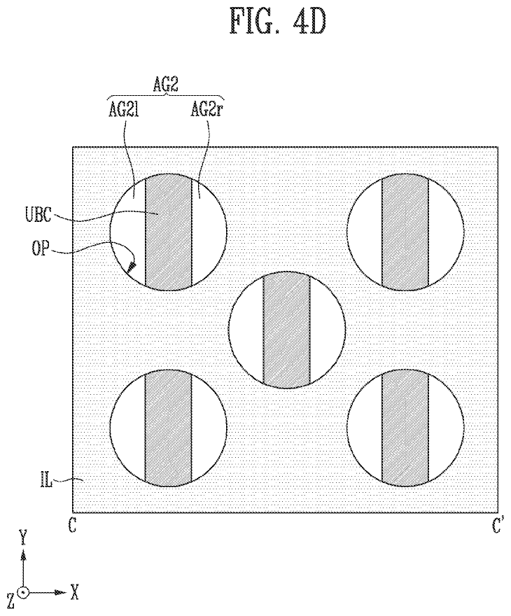

Referring to FIG. 3, a distance between neighboring bit lines BL (e.g. the first bit line BL1 and the second bit line BL2) in the X direction may be smaller than a distance between neighboring cell plugs CP in the X direction. As the distance between the neighboring bit lines BL in the X direction is reduced, the parasitic capacitance between the bit lines BL may be increased. According to the present disclosure, the parasitic capacitance between the bit lines BL may be reduced through air gaps formed between the bit lines BL. The air gaps will be described below with reference to FIGS. 4A to 4D.

FIGS. 4A to 4D are views illustrating the structure of the memory device according to an embodiment of the present disclosure. FIG. 4A is a sectional view taken along line A-A′ of FIG. 3. FIG. 4B is a perspective view showing the structure of the bit lines BL1 to BL3 and upper bit line contacts UBC of FIG. 4A. FIG. 4C is a plan view corresponding to a section taken along line B-B′ of FIG. 4A. FIG. 4D is a plan view corresponding to a section taken along line C-C′ of FIG. 4A.

Referring to FIGS. 4A and 4B, the memory device 100 may include cell plugs CP, an insulating pattern IL on the cell plugs CP, bit lines BL1, BL2, and BL3 on the insulating pattern IL, bit line contacts BC coupling the cell plugs CP to the bit lines BL1 and BL3, and air gaps AG. The memory device 100 may further include a contact plug CC coupling each of the cell plugs CP and each of the bit line contacts BC.

The memory device 100 may include the cell plugs CP. Each cell plug CP may include the blocking layer BX, the charge trap layer CT, the tunnel isolation layer TX, the channel layer CH, and the core pillar CO. The cell plugs CP may penetrate conductive layers CD and interlayer insulating layers IIL, which are alternately stacked, in the Z direction.

The insulating layer ILL and the contact plugs CC penetrating the insulating layer ILL may be formed on the cell plugs CP. The contact plugs CC may contact the cell plugs CP, respectively. The contact plugs CC may be electrically connected to the cell plugs CP.

The insulating pattern IL and the bit line contacts BC may be formed on the cell plugs CP. For example, the insulating pattern IL and the bit line contacts BC may be positioned on the insulating layer ILL and the contact plugs CC. The bit line contacts BC may contact the contact plugs CC, respectively. The bit line contacts BC may be coupled through the contact plugs CC to the cell plugs CP, respectively.

Although FIG. 4A shows that the cell plugs CP are coupled through the contact plugs CC to the bit line contacts BC, this is only one example and a variety of different embodiments are possible. For example, the cell plugs CP may be directly coupled to the bit line contacts BC. Further, although FIG. 4A shows that the core pillar CO included in each cell plug CP contacts the contact plug CC, the present disclosure is not limited thereto. For example, the cell plugs CP may further include a capping layer formed on the core pillar CO, and the capping layer may contact the contact plugs CC.

The insulating pattern IL may be formed on the cell plugs CP. For example, the insulating pattern IL may contact the upper surface of the insulating layer ILL. In an embodiment, the insulating pattern IL may include openings OP that correspond to the cell plugs CP, respectively. The openings OP may be formed to correspond to the positions of the cell plugs CP. For example, at least a portion of the opening OP may overlap the cell plug CP. Alternatively, at least a portion of the cell plug CP may overlap the opening OP. In an embodiment, the openings OP may be formed to correspond to the positions of the contact plugs CC. At least a portion of the opening OP may overlap the contact plug CC. The opening OP may expose at least a portion of the upper surface of the contact plug CC.

The bit lines BL1, BL2, and BL3 may be formed on the insulating pattern IL. Each of the bit lines BL1, BL2, and BL3 may extend in the Y direction. The bit lines BL1, BL2, and BL3 may be formed of molybdenum (Mo). The bit lines BL1, BL2, and BL3 may be formed as a single layer. For example, the bit lines BL1, BL2, and BL3 might not contain a barrier metal or a metal seed layer. Therefore, the resistance of the bit lines BL1, BL2, and BL3 may be reduced when the bit lines BL1, BL2, and BL3 are formed of molybdenum compared to the case where the bit lines BL1, BL2, and BL3 are formed of copper (Cu) or tungsten (W).

The bit line contacts BC may be formed in the openings OP. The bit line contacts BC may couple the cell plugs CP to the bit lines BL1, BL2, and BL3, respectively. For example, the bit line contacts BC may couple any one of the cell plugs CP to the first bit line BL1, and may couple another cell plug CP to a third bit line BL3.

Each of the bit line contacts BC may include the upper bit line contact UBC extending from each of the bit lines BL1 and BL3, and a lower bit line contact LBC contacting the lower surface of the upper bit line contact UBC.

The upper bit line contacts UBC may be integrally formed on each of the bit lines BL1, BL2, and BL3. A width of the upper bit line contact UBC in the X direction may be the same as that of each of the bit lines BL1, BL2, and BL3 in the X direction. For example, a side surface of the upper bit line contact UBC in the X direction may extend from a side surface of each of the bit lines BL1, BL2, and BL3 in the X direction. Further, a width of the upper bit line contact UBC in the Y direction may be the same as that of each of the openings OP in the Y direction. For example, a side surface of the upper bit line contact UBC in the Y direction may be coplanar with the inner wall of each of the openings OP. Referring to FIGS. 4B and 4D, the side surface of the upper bit line contact UBC in the Y direction may contact the inner wall of the opening OP. Further, the side surface of the upper bit line contact UBC in the X direction may be spaced apart from the inner wall of the opening OP. A second air gap AG2 may be formed between the side surface of the upper bit line contact UBC in the X direction and the inner wall of the opening OP.

The upper bit line contact UBC may be formed of molybdenum. Molybdenum is relatively higher in step coverage than copper or tungsten. Thus, the incidence of gap fill defects, where a high aspect ratio structure (e.g. a structure in which the first bit line BL1 and the upper bit line contact UBC are integrally formed) is not sufficiently filled with metal, may be reduced with molybdenum filling compared to copper or tungsten filling.

The lower bit line contact LBC may be formed of tungsten or copper. The lower bit line contact LBC may be wider than the upper bit line contact UBC. For example, the lower bit line contact LBC may have the same width as each opening OP. The lower bit line contact LBC may have a recessed shape compared to the upper surface of the insulating pattern IL. As the lower bit line contact LBC has the recessed shape compared to the upper surface of the insulating pattern IL, the volume of the air gaps AG may be increased.

The memory device 100 may further include a capping layer CAP that covers upper surfaces of the bit lines BL1, BL2, and BL3 and extends in the horizontal direction (e.g., the X direction and the Y direction). The capping layer CAP may further cover upper surfaces of the bit lines BL1, BL2, and BL3 and at least some areas of sidewalls of the bit lines BL1, BL2, and BL3. The capping layer CAP may be formed of an oxide layer. The capping layer CAP may be formed of a material having a low dielectric constant to reduce capacitance between the bit lines BL1, BL2, and BL3.

The capping layer CAP may be formed of a material having a relatively low step coverage. As the step coverage of the material forming the capping layer CAP decreases, the volume of the air gaps AG may increase.

The memory device 100 may include the air gaps AG. The air gaps AG may include first air gaps AG1 between the bit lines BL1, BL2, and BL3, and second air gaps AG2 extending from the first air gaps AG1 and enclosed by the bit line contacts BC and the insulating pattern IL. The first air gaps AG1 and the second air gaps AG2 may extend from each other.

The first air gaps AG1 may be enclosed by the capping layer CAP, the sidewalls of the bit lines BL1, BL2, and BL3, the upper surface of the insulating pattern IL, and the second air gaps AG2. The first air gaps AG1 may be enclosed by the capping layer CAP, the upper surface of the insulating pattern IL, and the second air gaps AG2. Each of the first air gaps AG1 may partially overlap the insulating pattern IL. For example, the lower surface of each of the first air gaps AG1 may contact both the second air gap AG2 and the upper surface of the insulating pattern IL.

The second air gaps AG2 may be enclosed by the first air gaps AG1, the sidewall of the upper bit line contact UBC, the inner wall of each opening OP, and the upper surface of the lower bit line contact LBC. Each of the second air gaps AG2 may be positioned in each opening OP along with the bit line contact BC. As the length of the lower bit line contact LBC in the Z direction decreases, the volume of the second air gaps AG2 may increase.

Referring to FIG. 4C, each of the first air gaps AG1 may extend in a direction in which each of the bit lines BL1, BL2, and BL3 extends. For example, each of the first air gaps AG1 may extend in the Y direction. Each of the first air gaps AG1 may be positioned between the bit lines BL1, BL2, and BL3 to reduce parasitic capacitance between the bit lines BL1, BL2, and BL3.

Referring to FIG. 4D, two separate second air gaps AG2l and AG2r may be positioned in any one opening OP. For example, any one second air gap AG2l may be formed on one side of the upper bit line contact UBC, and another second air gap AG2r may be formed on the other side of the upper bit line contact UBC. The two second air gaps AG2l and AG2r positioned in one opening OP may be separated from each other by the upper bit line contact UBC. Referring to FIGS. 4A and 4D, the first air gaps AG1 positioned on opposite sides of the first bit line BL1 may extend, respectively, to the second air gaps AG2l and AG2r on opposite sides of the upper bit line contact UBC extending from the first bit line BL1.

The second air gaps AG2 may be enclosed by the sidewalls of the upper bit line contacts UBC and the inner walls of the openings OP. Because the second air gaps AG2 are positioned at levels corresponding to the upper bit line contacts UBC, parasitic capacitance between the upper bit line contacts UBC may be reduced.

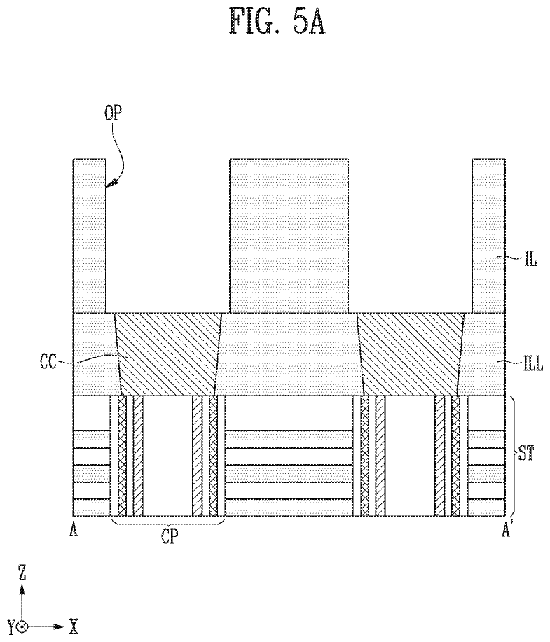

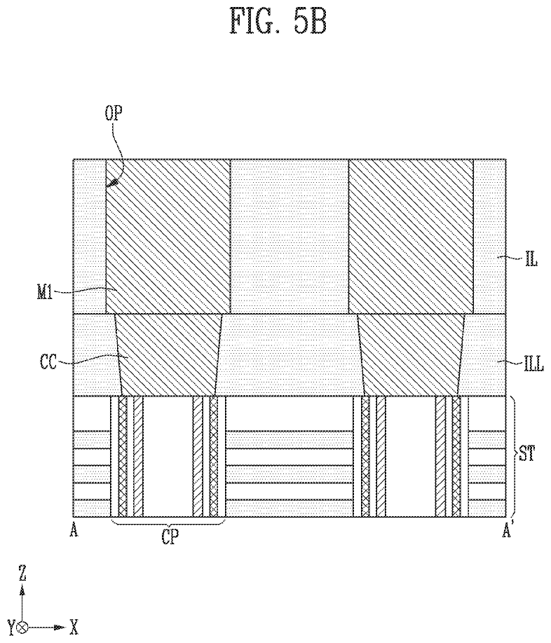

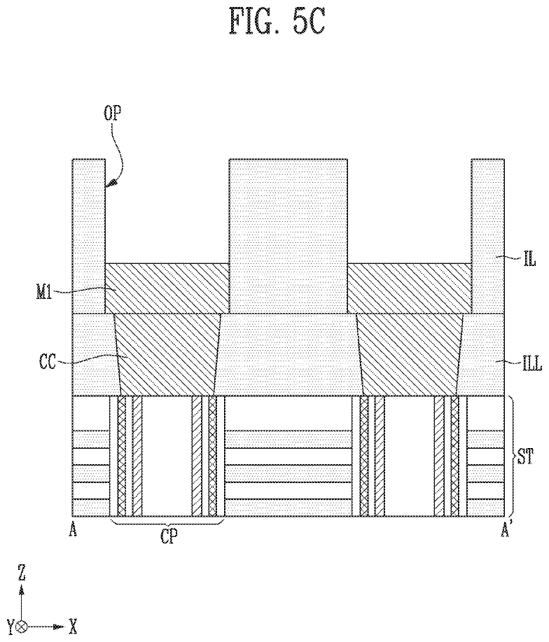

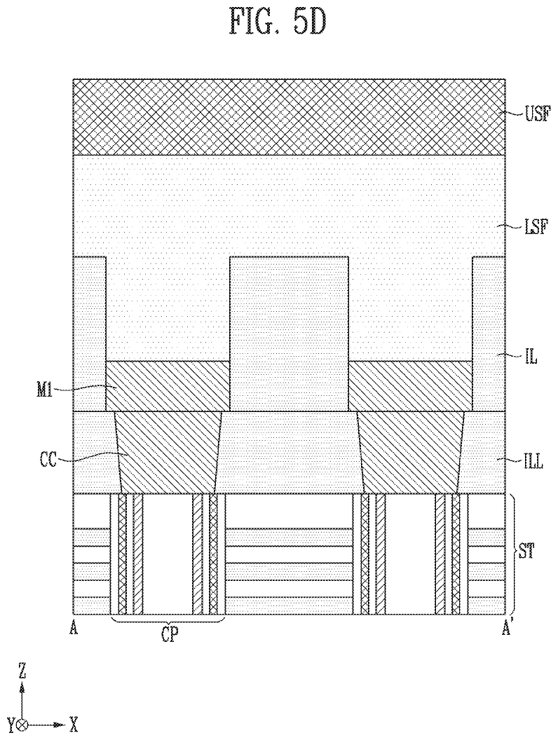

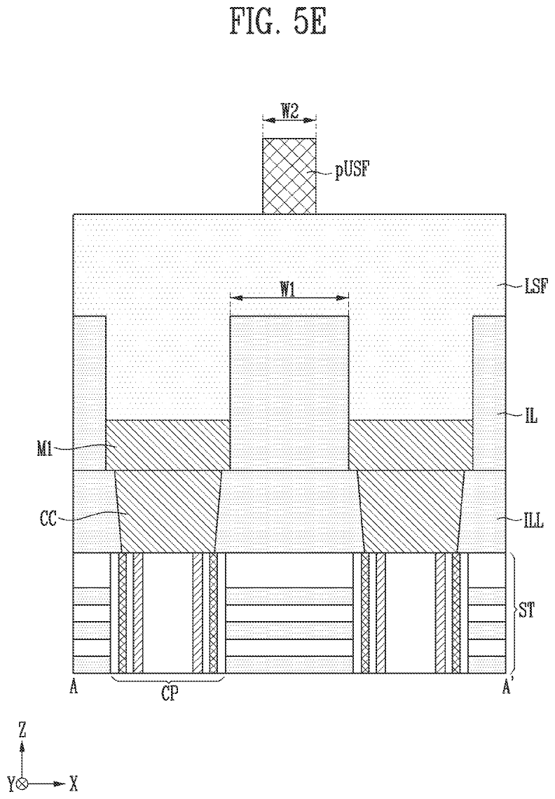

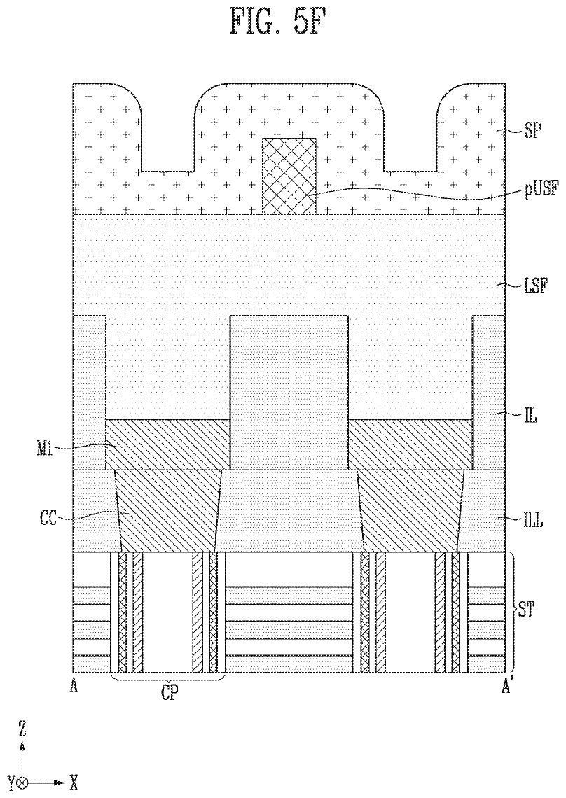

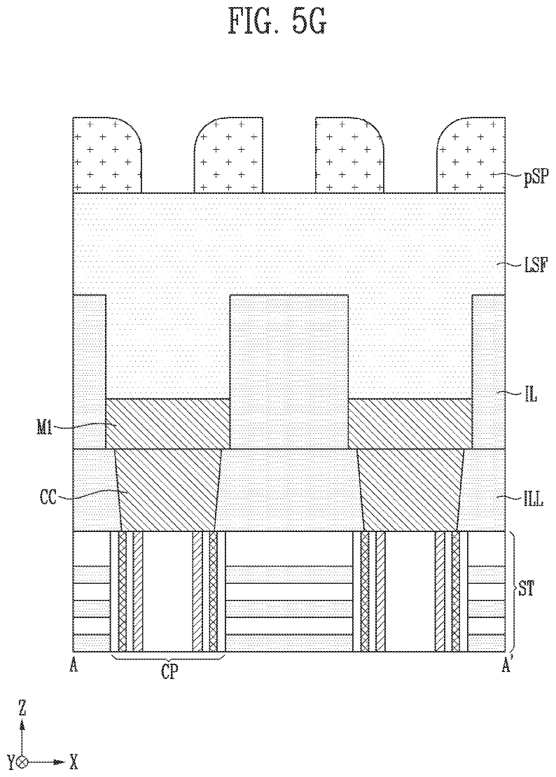

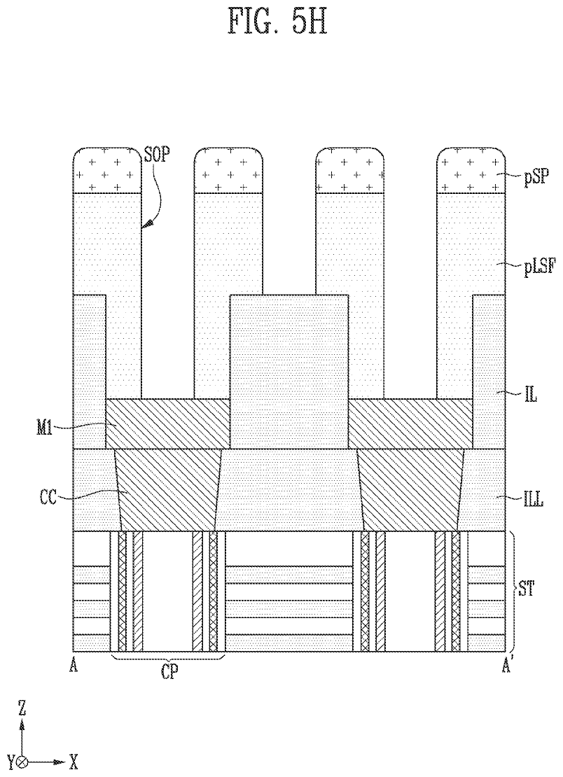

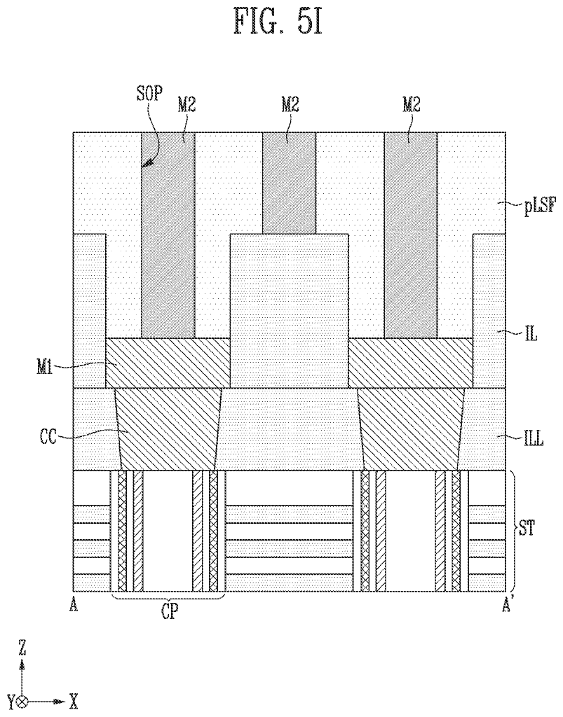

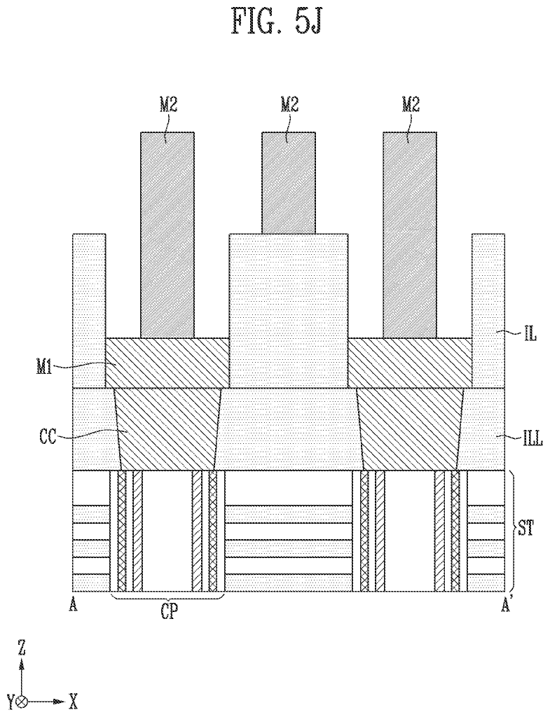

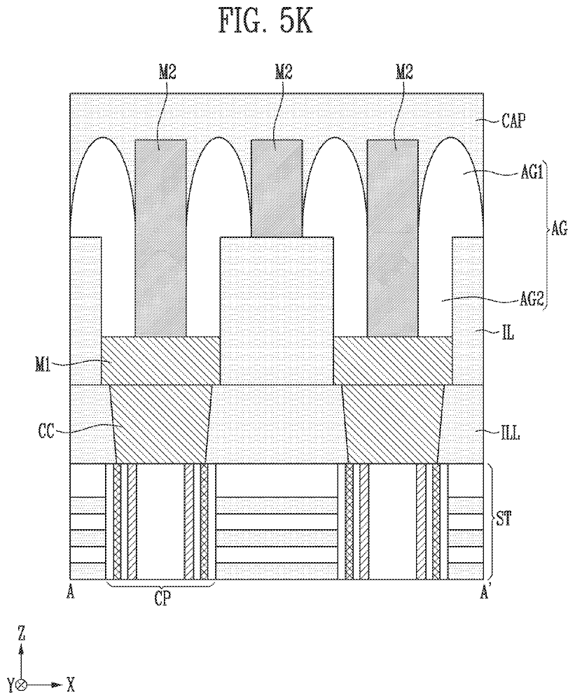

FIGS. 5A to 5K are views illustrating a method of manufacturing a memory device according to an embodiment of the present disclosure. FIGS. 5A to 5K are sectional views taken along line A-A′ of FIG. 3.

Referring to FIG. 5A, the cell plugs CP may be formed to penetrate a stacked body ST. The first insulating layer ILL may be formed on the cell plugs CP. Further, the contact plugs CC may be formed to penetrate the first insulating layer ILL. The contact plugs CC may be formed to contact the cell plug CP.

A second insulating layer may be formed on the cell plugs CP. For example, the second insulating layer may be formed on the first insulating layer ILL. A portion of the second insulating layer may be etched to form the insulating pattern IL. For example, a portion of the second insulating layer may be etched to form the openings OP for exposing the contact plugs CC. The insulating pattern IL may include the openings OP which at least partially overlap the cell plugs CP.

Referring to FIG. 5B, first material layers M1 may be formed in the openings OP. The first material layers M1 may be formed to fill the openings OP. The first material layers M1 may be a conductive layer such as tungsten. For example, the first material layers M1 may be formed of the same material as the contact plugs CC.

Referring to FIG. 5C, the first material layers M1 may be formed to fill the lower portions of the openings OP. For example, an etch-back process may be performed to etch portions of the first material layers M1 filled in the openings OP. As portions of the first material layers M1 in the openings OP are etched, a portion of the inner wall of each opening OP may be exposed. As portions of the first material layers M1 are etched, the first material layers M1 may have a recessed shape compared to the upper surface of the insulating pattern IL. That is, the first material layers M1 may be thinner in thickness than the insulating pattern IL.

Referring to FIG. 5D, a lower sacrificial layer LSF may be formed on an entire structure including the first material layers M1. The lower sacrificial layer LSF may be formed to cover the first material layers M1 and the insulating pattern IL. The lower sacrificial layer LSF may fill the openings OP of the insulating pattern IL. The lower sacrificial layer LSF may be a polysilicon layer. An upper sacrificial layer USF may be formed on the lower sacrificial layer LSF. The upper sacrificial layer USF may be an amorphous carbon layer ACL.

Referring to FIG. 5E, a portion of the upper sacrificial layer USF may be etched to form an upper sacrificial pattern pUSF that exposes a portion of the lower sacrificial layer LSF. The upper sacrificial pattern pUSF may be formed so as not to overlap the openings OP of the insulating pattern IL. Assuming that the insulating pattern IL between the openings OP has a first width W1, the upper sacrificial pattern pUSF may have a second width W2 narrower than the first width W1.

Referring to FIG. 5F, a spacer SP may be formed along a surface of the upper sacrificial pattern pUSF and a surface of the lower sacrificial layer LSF. The spacer SP may be formed of a material that is different in etch selectivity from that of the upper sacrificial pattern pUSF. For example, the spacer SP may be formed of an insulating material such as the oxide layer.

Referring to FIG. 5G, a portion of the spacer SP and the upper sacrificial pattern pUSF may be etched to form the spacer pattern pSP. For example, the etch-back process may be performed to expose the upper sacrificial pattern pUSF and a portion of the lower sacrificial layer LSF. The etch-back process may be performed by an anisotropic dry etching process. When the etch-back process is performed on the entire structure in which the spacer SP is formed, the spacer SP formed in the horizontal direction (e.g., the X direction and the Y direction) may be removed. Therefore, the spacer SP formed in the Z direction on the side surface of the upper sacrificial pattern pUSF may remain as the spacer pattern pSP. The spacer pattern pSP may expose a portion of the lower sacrificial layer LSF on the lower sacrificial layer LSF.

Referring to FIG. 5H, the etching process may be performed to remove a portion of the lower sacrificial layer LSF exposed by the spacer pattern pSP. The anisotropic dry etching process may be performed as the etching process for removing a portion of the lower sacrificial layer LSF. When a portion of the lower sacrificial layer LSF is removed, the lower sacrificial pattern pLSF including the sacrificial openings SOP that expose a portion of each first material layer M1 may remain. While a portion of the lower sacrificial layer LSF is etched using the spacer pattern pSP, the height of the spacer pattern pSP may be reduced.

Each of the sacrificial openings SOP included in the lower sacrificial pattern pLSF may expose a portion of the upper surface of each of the first material layers M1. Further, each of the sacrificial openings SOP included in the lower sacrificial pattern pLSF may expose a portion of the upper surface of the insulating pattern IL. In an area where the upper surface of the insulating pattern IL is exposed while the lower sacrificial layer LSF is being etched, etching may be stopped at a level corresponding to the upper surface of the insulating pattern IL. In an area where the upper surface of each first material layer M1 is exposed through the opening OP while the lower sacrificial layer LSF is being etched, etching may be stopped at a level corresponding to the upper surface of each of the first material layers M1. Because the etching depth of the sacrificial openings SOP varies depending on a position on the insulating pattern IL, the upper bit line contact UBC may be formed as shown in FIGS. 4B and 4D.

Referring to FIG. 51, after the lower sacrificial pattern pLSF is formed, the spacer pattern pSP may be removed.

The sacrificial openings SOP may be filled with second material layers M2. Because the bit lines and the upper bit line contact should be integrally formed in the sacrificial openings SOP, the aspect ratio of the sacrificial openings SOP may increase. Therefore, the second material layers M2 for filling the interiors of the sacrificial openings SOP may be selected from among conductive materials having a high step coverage. For example, the second material layers M2 may be formed of molybdenum. Because molybdenum has a high step coverage characteristic, the interiors of the sacrificial openings SOP may be sufficiently filled even if the aspect ratio of the sacrificial openings SOP is increased compared to a conventional case. Further, each of the second material layers M2 may be formed of a single layer. As molybdenum having the high step coverage is used for the second material layers M2, the step of forming the barrier metal or the metal seed layer may be omitted before the step of filling the sacrificial openings SOP with the second material layers M2. Therefore, according to the present disclosure, a manufacturing process may be simplified compared to the case where the barrier metal or metal seed layer is required. Further, because the second material layers M2 positioned above the upper surface of the insulating pattern IL, among the second material layers M2 filled in the sacrificial openings SOP, become the bit lines BL1 to BL3 (see FIG. 4A) and the second material layers M2 positioned between the insulating patterns IL become the upper bit line contacts UBC (see FIG. 4A), resistance between the bit lines and the upper bit line contacts may be reduced.

Referring to FIG. 5J, the etching process may be performed to remove the lower sacrificial pattern pLSF. For example, a dry etching process or a wet etching process may be performed on the lower sacrificial pattern pLSF that is higher in etch selectivity than the second material layers M2, the insulating pattern IL, and the first material layers M1. As the lower sacrificial pattern pLSF is removed, the second material layers M2 may be exposed, and the first material layers M1 may also be exposed between the insulating patterns IL.

Referring to FIG. 5K, the capping layer CAP may be formed on the second material layers M2. The capping layer CAP may be formed of an insulating material having a low step coverage such that the air gap AG is formed between the second material layers M2 and in the openings OP. The air gap AG may include the first air gap AG1 and the second air gap AG2 positioned under the first air gap AG1. The first air gap AG1 may be enclosed by the sidewalls of the second material layers M2 and the capping layer CAP. Alternatively, the first air gap AG1 may be enclosed by the capping layer CAP. Further, the second air gap AG2 may be enclosed by the sidewalls of the second material layers M2, the inner walls of the openings OP, and the upper surfaces of the first material layers M1.

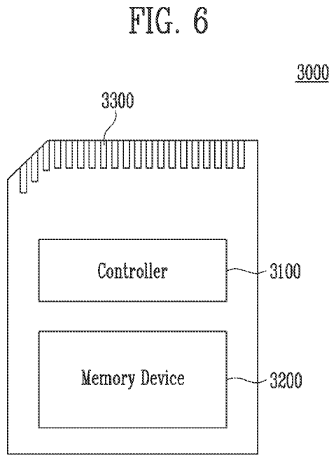

FIG. 6 is a diagram illustrating a memory card system to which a memory device according to an embodiment of the present disclosure is applied.

Referring to FIG. 6, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as random-access memory (RAM), a processor, a host interface, a memory interface, and an error corrector.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include a plurality of memory cells and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

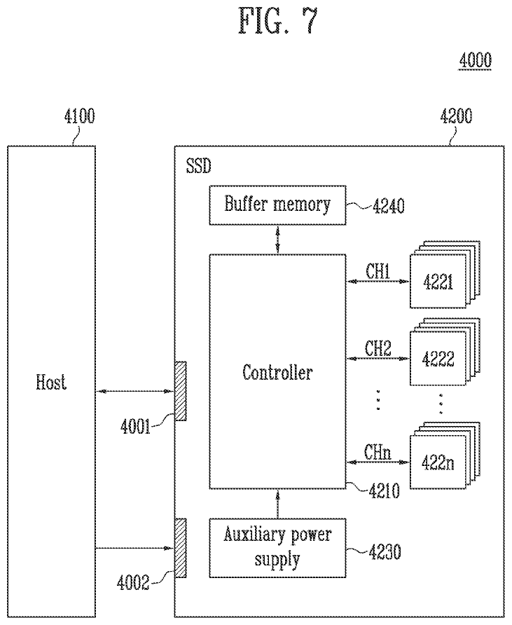

FIG. 7 is a diagram illustrating a solid-state drive (SSD) system to which a memory device according to the present disclosure is applied.

Referring to FIG. 7, an SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may

include a plurality of memory cells configured to store data. Each of the memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located in a main board, and may provide auxiliary power to the SSD 4200.

The buffer memory 4240 may function as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memory, such as dynamic random-access memory (DRAM), synchronous DRAM (SDRAM), double data rate (DDR) SDRAM, and low-power DDR (LPDDR) SDRAM, or nonvolatile memory, such as ferroelectric RAM (FRAM), resistive RAM (ReRAM), spin transfer torque magnetic RAM (STT-MRAM), and phase-change RAM (PRAM).

According to the present disclosure, resistance of bit lines and parasitic capacitance between the bit lines may be reduced, and a manufacturing process for a memory device may be simplified.

What is claimed is:

1. A memory device, comprising:
cell plugs;
an insulating pattern disposed on the cell plugs and including openings corresponding to the cell plugs, respectively;
bit lines disposed on the insulating pattern;
bit line contacts disposed in the openings to couple the cell plugs and the bit lines, respectively;
first air gaps disposed between the bit lines; and
second air gaps extending from the first air gaps and enclosed by the bit line contacts and the insulating pattern.

2. The memory device according to claim 1, wherein the bit lines are comprised of molybdenum (Mo).

3. The memory device according to claim 1, wherein each of the bit line contacts comprises:
an upper bit line contact extending from each of the bit lines; and
a lower bit line contact contacting a lower surface of the upper bit line contact.

4. The memory device according to claim 3, wherein the upper bit line contact is comprised of molybdenum.

5. The memory device according to claim 3, wherein the upper bit line contact has a width equal to a width of each of the bit lines.

6. The memory device according to claim 3, wherein the upper bit line contact contacts a portion of an inner wall of each of the openings.

7. The memory device according to claim 3, wherein the lower bit line contact fills a lower portion of each of the openings.

8. The memory device according to claim 3, wherein each of the second air gaps is enclosed by each of the first air gaps, a sidewall of the upper bit line contact, an inner wall of each of the openings, and an upper surface of the lower bit line contact.

9. The memory device according to claim 1, further comprising:
a capping layer covering upper surfaces of the bit lines and extending in a horizontal direction.

10. The memory device according to claim 9, wherein the capping layer is an oxide layer.

11. The memory device according to claim 9, wherein the first air gaps are enclosed by the capping layer, sidewalls of the bit lines, an upper surface of the insulating pattern, and the second air gaps.

12. The memory device according to claim 1, wherein each of the first air gaps partially overlaps the insulating pattern.

13. The memory device according to claim 1, wherein each of the first air gaps extends in a direction in which each of the bit lines extends.

14. The memory device according to claim 1, wherein the bit line contacts and the second air gaps are positioned in the openings.

15. A method of manufacturing a memory device, the method comprising:
forming an insulating layer on cell plugs;
etching a portion of the insulating layer to form openings that at least partially overlap the cell plugs;
forming first material layers to fill respective lower portions of the openings;
forming a lower sacrificial layer on an entire structure including the first material layers;
forming a spacer pattern on the lower sacrificial layer to expose a portion of the lower sacrificial layer;
etching the lower sacrificial layer exposed by the spacer pattern to form sacrificial openings that expose respective portions of the first material layers;
filling the sacrificial openings with second material layers;
removing the lower sacrificial layer; and
forming a capping layer on the second material layers to form air gaps between the second material layers and between the second material layers and the openings.

16. The method according to claim 15, wherein forming the first material layers to fill the respective lower portions of the openings comprises:
forming the first material layers in the openings; and
etching a portion of each of the first material layers to expose a portion of an inner wall of each of the openings.

17. The method according to claim 15, wherein forming the spacer pattern on the lower sacrificial layer comprises:
forming an upper sacrificial layer on the lower sacrificial layer;
etching a portion of the upper sacrificial layer to form an upper sacrificial pattern that exposes a portion of the lower sacrificial layer;
forming a spacer on the upper sacrificial pattern; and
etching a portion of the spacer and the upper sacrificial pattern to form the spacer pattern.

18. The method according to claim 15, wherein the second material layers are comprised of molybdenum.

19. The method according to claim 18, wherein the second material layers are formed in a single layer.

20. The method according to claim 15, wherein the air gap is formed to comprise:
a first air gap enclosed by sidewalls of the second material layers and the capping layer; and
a second air gap enclosed by the sidewalls of the second material layers, inner walls of the openings, and upper surfaces of the first material layers.
